(19) United States
(12) Patent Application Publication
(10) Pub. No.: US 2008/0211085 A1
(43) Pub. Date: Sep. 4, 2008

(54) Semiconductor package having insulating substrate

(76) Inventors: Chia-Ming Fan, Keelung City (TW); Chen-Chih Hung, Keelung City (TW); Ching-Shou Hsu, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/896,137

(22) Filed: Aug. 30, 2007

(30) Foreign Application Priority Data
Mar. 2, 2007 (TW) 96203478

(51) Int. Cl. H01L 23/12

(52) U.S. Cl. 257/701; 257/E23.003

(57) ABSTRACT

A semiconductor package having an insulating substrate includes a dielectric layer, a set of metal layers, a set of supporting elements, and an electronic component. The set of metal layers includes a first metal layer and a second metal layer respectively located on the upper surface and the lower surface of the dielectric layer. The set of supporting elements includes a first supporting element and a second supporting element respectively located on the first metal layer and the second metal layer. The electronic component is electrically connected with the first supporting element. The dielectric layer and the set of metal layers form an insulating substrate. Furthermore, a package resin is disposed on the second supporting element to package the dielectric layer, the set of metal layers, the first supporting element, and the electronic component into one piece and fasten it on to the second supporting element.

### BACKGROUND OF THE INVENTION

1. Field of the Invention

The present invention relates to a semiconductor package having an insulating substrate. In particular, this invention relates to an improved insulating substrate that disposes a dielectric layer and a set of metal layers in a semiconductor package to achieve the insulating and heat-conducting effect, improve the structure, simplify the manufacturing process, and reduce the required material.

2. Description of the Related Art

Heat-conducting bases having an electrical insulating effect are extensively applied to the electronic industry for conducting heat and protecting a variety of electronic devices. Generally, the heat-conducting base having an electrical insulating effect achieves the electrical insulating effect via a metal substrate including at least one ceramic element. However, the problem arises of how to assemble the ceramic element and the metal substrate when the heat-conducting base having an electrical insulating effect is manufactured.

Currently, the electronic industry can form a Ni metal layer on the ceramic element, and use the Ni metal as a soldering material for connecting the ceramic element with the metal substrate of the heat-conducting base having an electrical insulating effect. The Ni metal layer is formed on the Mo—Mn layer of the ceramic element, and the Ni metal layer is used as a soft-solder joint between the ceramic element and the metal substrate of the heat-conducting base having an electrical insulating effect.

The above method for connecting the ceramic element is widely accepted by the electronic industry. However, there are some problems in the method using a nickel-plating. For example, when Ni is compared with other metals (such as Cu), Ni has low thermal conductivity and electric conductivity. Moreover, compared with other metals, Ni is weaker. The manufacturing process for the Ni is time-consuming and expensive.

Furthermore, when the electronic device is being manufactured, metal conducting pins or connecting pins are formed on the ceramic for supporting the electronic device. For example, conducting wires or conducting pins are formed on the ceramic having a semiconductor chip. Moreover, Ni, or similar metals with high impedance that are not suitable for the application, needs high current. Therefore, for application to the semiconductor packaging industry, a conducting element that is easily formed on the semiconductor and has low impedance for a high current application is required.

### SUMMARY OF THE INVENTION

One particular aspect of the present invention is to provide a semiconductor package having an insulating substrate. This invention disposes a dielectric layer and a set of metal layers in a semiconductor package. It utilizes the package resin to package the dielectric layer, the set of metal layers, the set of supporting elements, and the electronic components into one piece. Thereby, the package structure achieves the insulating and heat-conducting effect, and improves the dimension and structure of package.

The semiconductor package having an insulating substrate includes a dielectric layer, a set of metal layers, a set of supporting elements, and an electronic component. The set of metal layers includes a first metal layer and a second metal layer that are respectively located on the upper surface and the lower surface of the dielectric layer. The set of supporting elements includes a first supporting element and a second supporting element that are respectively located on the surfaces of the first metal layer and the second metal layer. The electronic component is electrically connected with the first supporting element. The dielectric layer and the set of metal layers form an insulating substrate.

The present invention disposes a package resin on the second supporting element. The package resin packages the dielectric layer, the first and second metal layers, the first supporting element and the electronic component into one piece and fastens it on to the second supporting element so that the first supporting element protrudes to the outside of the package resin. Thereby, due to the insulating substrate, the package structure achieves the insulating and heat-conducting effect, improves the dimension and structure of the package structure, simplifies the manufacturing process, and reduces the required material.

For further understanding of the invention, reference is made to the following detailed description illustrating the embodiments and examples of the invention. The description is only for illustrating the invention and is not intended to be considered limiting of the scope of the claim.

### BRIEF DESCRIPTION OF THE DRAWINGS

The drawings included herein provide a further understanding of the invention. A brief introduction of the drawings is as follows:

FIG. 1A is a schematic diagram of a dielectric layer and a metal layer formed on a wafer of the semiconductor package having an insulating substrate of the present invention;

FIG. 1B is a cross-sectional view of the dielectric layer and the set of metal layers connected to form an insulating substrate of the semiconductor package having an insulating substrate of the present invention;

FIG. 1C is a cross-sectional view of the dielectric layer, the set of metal layers and the electronic component connected together of the semiconductor package having an insulating substrate of the present invention;

FIG. 2 is a schematic diagram of the two supporting elements of the semiconductor package having an insulating substrate of the present invention before assembly;

FIG. 3 is a schematic diagram of the insulating substrate installed with a supporting element of the semiconductor package having an insulating substrate of the present invention;

FIG. 4 is a schematic diagram of the insulating substrate connected with two supporting elements of the semiconductor package having an insulating substrate of the present invention;

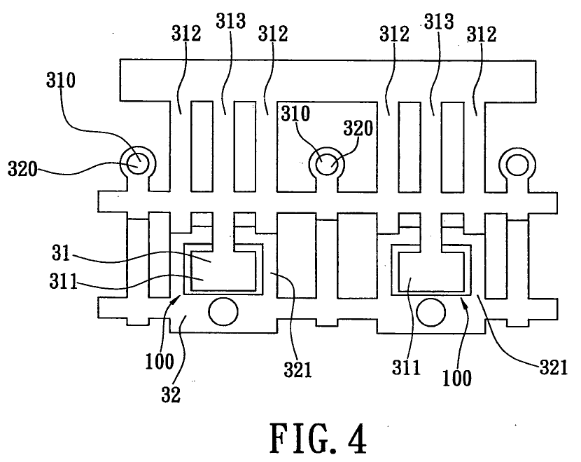

FIG. 5 is a schematic diagram of the insulating substrate connected with the connecting pins of the supporting element of the semiconductor package having an insulating substrate of the present invention;

FIG. 6 is a schematic diagram of the insulating substrate connected with the two supporting elements and packaged by the package resin of the semiconductor package having an insulating substrate of the present invention;

FIG. 7 is a schematic diagram of the semiconductor package having an insulating substrate of the present invention; and

FIG. 8 is a cross-sectional view of the semiconductor package having an insulating substrate of the present invention.

### DETAILED DESCRIPTION OF THE PREFERRED EMBODIMENTS

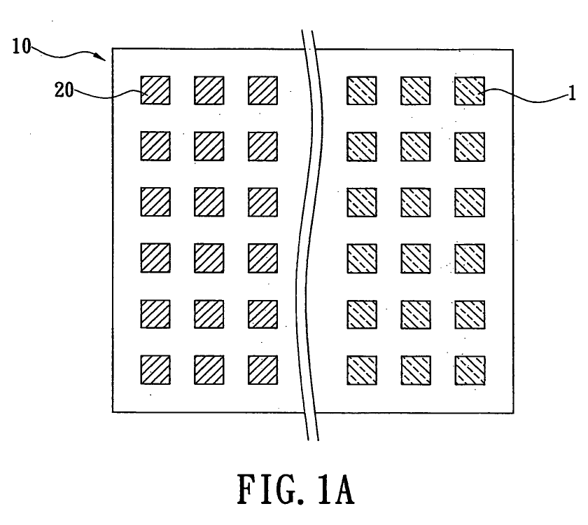

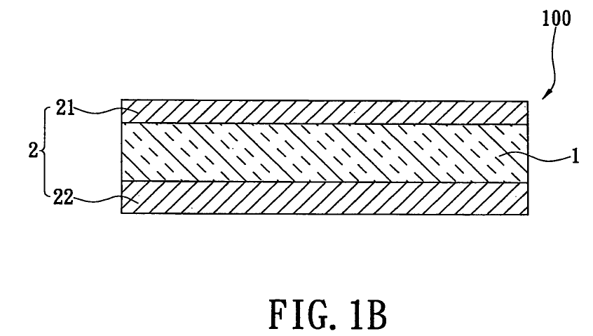

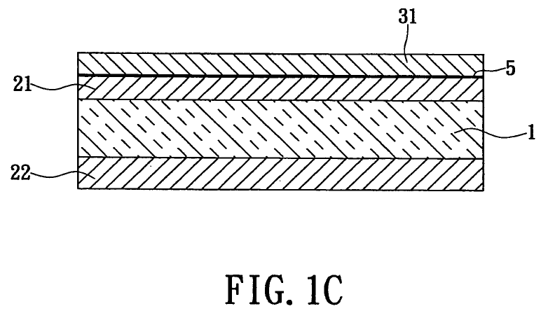

Reference is made to FIGS. 1A˜8, which shows an embodiment of the package structure of the present invention.

As shown in FIG. 1A, the present invention provides a wafer substrate 10. A plurality of dielectric layers 1 and metal layers 20 are formed on the wafer substrate 10. The plurality of dielectric layers 1 and metal layers 20 on the wafer substrate 10 can be divided individually. On the upper surface and the lower surface of the dielectric layer 1 there is a metal layer 20.

As shown in FIG. 1B, the two metal layers 20 respectively located on the upper surface and the lower surface of the dielectric layer 1 form a set of metal layers 2. The set of metal layers 2 is composed of a first metal layer 21 and a second metal layer 22. The dielectric layer 1 is made of dielectric materials that can insulate electricity. The first metal layer 21 and the second metal layer 22 are made of copper, copper alloy, aluminum, or aluminum alloy. The dielectric layer 1, the first metal layer 21 and the second metal layer 22 forms an improved insulating substrate 100. By utilizing the structure of the insulating substrate 100, the present invention achieves the insulating and heat-conducting effect, improves the dimension and structure of package structure, and reduces the manufacturing time, costs and required materials.

As shown in FIG. 1C, the first supporting element 31 is located on the first metal layer 21 through a soldering material connecting layer 5 to achieve the heat-conducting effect.

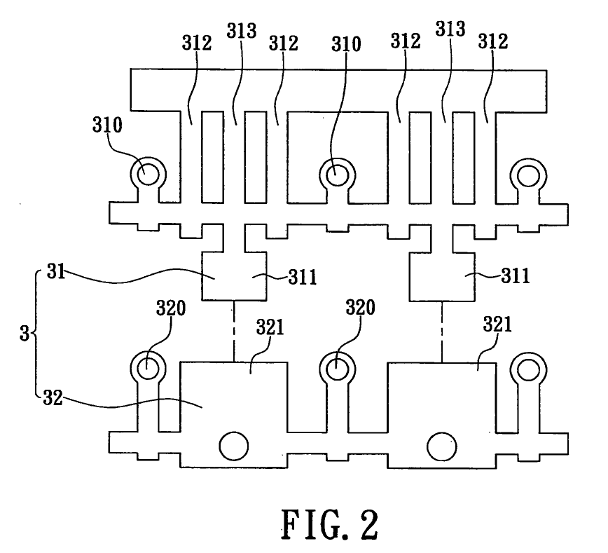

FIGS. 2˜6 show a schematic diagram of manufacturing the semiconductor package having an insulating substrate of the present invention.

FIG. 2 shows the first step of the assembly process. Firstly, a set of supporting elements 3 is provided. The set of supporting elements 3 is made of metal materials. The set of supporting elements 3 includes a first supporting element 31 located on the first metal layer 21, and a second supporting element 32 located on the second metal layer 22. The first supporting element 31 has a first aligning joint 310, a first jointing portion 311, a first connecting pin 312, and a second connecting pin 313. The second supporting element 32 has a second aligning joint 320, a second jointing portion 321. The first supporting element 31 and the second supporting element 32 uses the first aligning joint 310 and the second aligning joint 320 to make the first jointing portion 311 and the second jointing portion 321 be jointed together when they are joined on the insulating substrate 100.

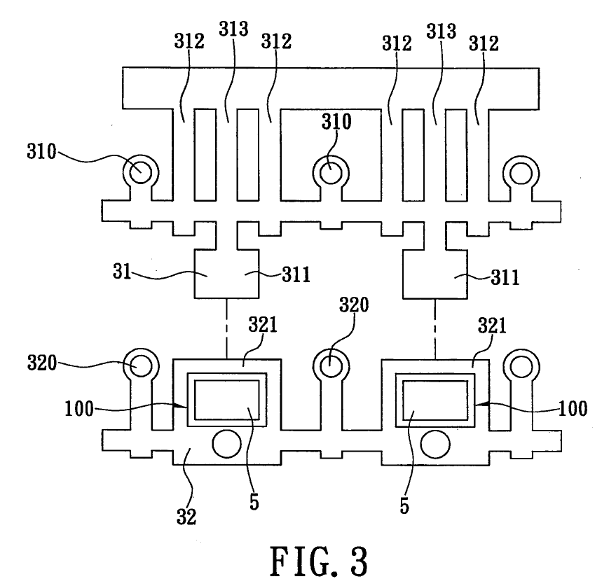

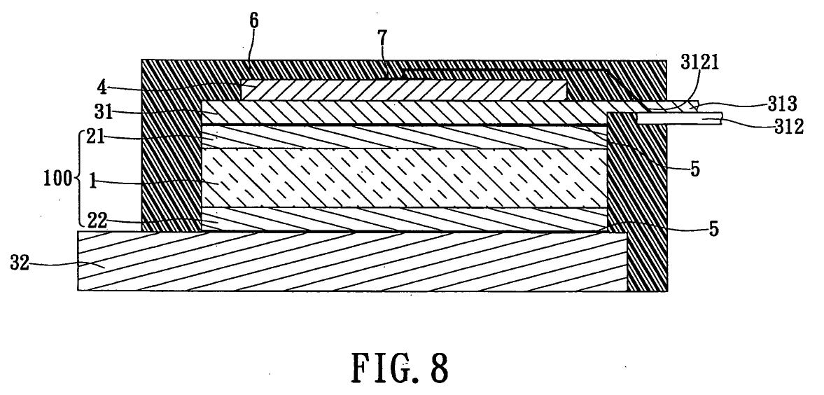

In FIGS. 3˜5, the surface of the second metal layer 22 of the insulating substrate 100 (the dielectric layer 1 and the set of metal layers 2 as shown in FIG. 1B) is located on the top surface of the second jointing portion 321 of the second supporting element 32. When the first supporting element 31 and the second supporting element are jointing, the first jointing portion 311 of the first supporting element is correspondingly jointed with the second jointing portion 321 of the second supporting element 32 by aligning the first aligning joint 310 with the second aligning joint 320, and the surface of the first jointing portion 311 is located on the top surface of the first metal layer 21 of the insulating substrate 100. When they are jointed, a soldering material connecting layer 5 is located between the first jointing portion 311 of the first supporting element 31 and the first metal layer 21 of the insulating substrate 100 to joint the first metal layer 21 with the first jointing portion 311. Furthermore, another soldering material connecting layer 5 (as shown in FIG. 8) is located between the second jointing portion 321 of the second supporting element 32 and the second metal layer 22 to joint the second jointing portion 321 with the bottom surface of the second metal layer 22.

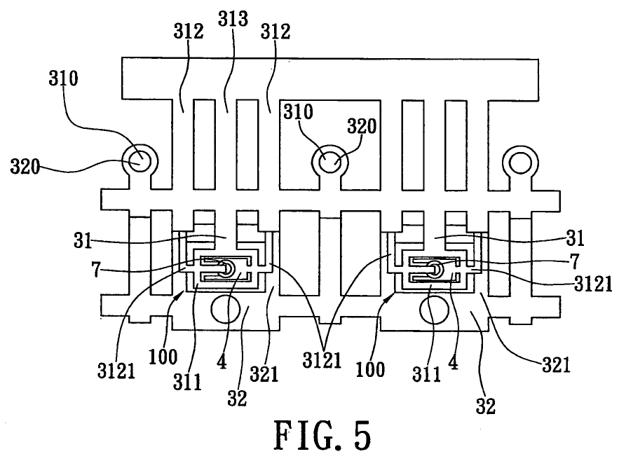

Reference is made to FIG. 5. After the first supporting element 31 and the second supporting element 32 are jointed, an electronic component 4 is located on the surface of the first jointing portion 311 of the first supporting element 31. There is a connecting element between the first supporting element 31 and the electronic component 4 for electrically connecting the first supporting element 31 with the electronic component 4, and cooperating with two clipping portions 3121 extending from the second connecting pin 312 to make the first supporting element 31 electrically and firmly be connected with the electronic component 4.

In this embodiment, the electronic component 4 is an IC chip for processing data or other similar electronic components. The electronic component 4 transmits a data signal by electrically connecting with the first supporting element 31.

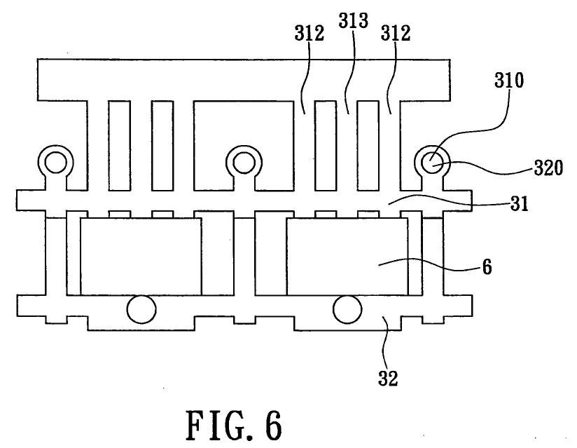

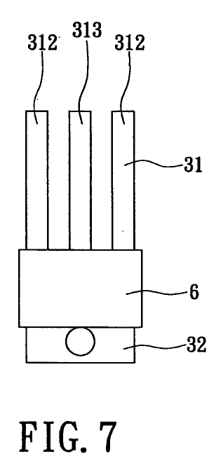

As shown in FIGS. 6˜8, after the jointing process is finished, a package resin 6 is disposed on the second supporting element 32. The package resin 6 packages the dielectric layer 1, the first metal layer 21, the second metal layer 22, the first supporting element 31, and the electronic component 4 that has been jointed into one piece and fastens it onto the second supporting element 32. Next, a cutting method implemented by a machine removes the redundant portion of the first supporting element 31 and the second supporting element 32 (such as the first aligning joint 310, the second aligning joint 320, and other connection structures). Thereby, a semiconductor package having an insulating substrate is formed (as shown in FIG. 7). The first connecting pin 312 and the second connecting pin 313 of the first supporting element 31 are exposed to the outside of the package resin 6 so that the electronic component 4 (IC chip) can transmit the processed data to another electronic component (not shown in the figure). The package resin 6 can be made of plastic materials, or epoxy materials that are suitable for electronic component.

FIG. 8 shows the semiconductor package having an insulating substrate of the present invention. The semiconductor package having an insulating substrate includes a dielectric layer 1, two metal layers 21, 22, two supporting elements 31, 32, and an electronic component 4. The two metal layers 21, 22 include a first metal layer 21 and a second metal layer 22 that are respectively located on the upper surface and the lower surface of the dielectric layer 1. The two supporting elements 31, 32 are a first supporting element 31 located on the first metal layer 21 and a second supporting element 32 located on the second metal layer 22. The electronic component 4 is electrically connected with the first supporting element 31. The first metal layer 21 and the second metal layer 22 are respectively connected with the first supporting element 31 and the second supporting element 32 through the soldering material connecting layer 5.

The present invention further includes a package resin 6 disposed on the second supporting element 32 (as shown in FIG. 7). The package resin 6 packages the dielectric layer 1, the first metal layer 21, the second metal layer 22, the first supporting element 31, and the electronic component 4 into one piece and fastens it onto the second supporting element 32.

The first connecting pin 312 and the second connecting pin 313 of the first supporting element 31 are respectively exposed to the outside of the package resin 6. On the surface of the electronic component 4, there is a connecting element 7 so that two first connecting pins 312 are connected with the connecting element 7 via the two clipping portions 3121, and the two first connecting pin 312 are electrically connected with the electronic component 4.

By using the insulating substrate composed of the dielectric layer 1, the first metal layer 21, and the second metal layer 22, the semiconductor package structure achieves the insulating and heat-conducting effect, improves the package structure, simplifies the manufacturing process, and reduces the required materials.

The present invention uses the dielectric layer and the set of metal layers to form the insulating substrate so that the semiconductor package having an insulating substrate has the following characteristics:

1. By using the insulating substrate, the semiconductor package structure achieves the insulating and heat-conducting effect, and simplifies the package structure.

2. Because the package structure is simplified, the manufacturing time is reduced, and the required materials and manufacturing costs are also lowered.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. A semiconductor package having an insulating substrate, comprising:
a dielectric layer;
a set of metal layers having a first metal layer and a second metal layer that are respectively located on the upper surface and the lower surface of the dielectric layer;
a set of supporting elements having a first supporting element located on the first metal layer and a second supporting element located on the second metal layer; and
an electronic component located on the first supporting element and electrically connected with the first supporting element;
wherein the dielectric layer and the set of metal layers form an insulating substrate.

2. The semiconductor package having an insulating substrate as claimed in claim 1, further comprising a package resin located on the second supporting element, wherein the package resin packages the dielectric layer, the first metal layer, the second metal layer, the first supporting element, and the electronic component into one piece and fastens it onto the second supporting element, and the first supporting element is exposed to the outside of the first supporting element.

3. The semiconductor package having an insulating substrate as claimed in claim 1, wherein the first metal layer and the second metal layer are made of copper or copper alloy.

4. The semiconductor package having an insulating substrate as claimed in claim 1, wherein the first metal layer and the second metal layer are made of aluminum or aluminum alloy.

5. The semiconductor package having an insulating substrate as claimed in claim 1, wherein there is a soldering material connecting layer located between the first metal layer and the first supporting element, and another soldering material connecting layer located between the second metal layer and the second supporting element.

6. The semiconductor package having an insulating substrate as claimed in claim 1, wherein there is a connecting element located between the first supporting element and the electronic component, and the connecting element is electrically connected with the first supporting element and the electronic component.

7. The semiconductor package having an insulating substrate as claimed in claim 1, wherein the first supporting element is a metal guiding frame, and the second supporting element is a heat-conducting base.

8. The semiconductor package having an insulating substrate as claimed in claim 1, wherein the electronic component is an IC chip.

9. A semiconductor package having an insulating substrate, comprising:
an insulating substrate having a first surface and a second surface;
a set of supporting elements having a first supporting element located on the first surface and a second supporting element located on the second surface; and
an electronic component located on the first supporting element.

10. The semiconductor package having an insulating substrate as claimed in claim 9, the insulating substrate having a dielectric layer, a first metal layer, and a second metal layer that are respectively located on the two opposite surfaces of the dielectric layer, the first metal layer and the second metal layer are made of copper or copper alloy, the first supporting element is located on the surface of the first metal layer, and the second supporting element is located on the surface of the second metal layer.

11. The semiconductor package having an insulating substrate as claimed in claim 10, further comprising a package resin, wherein the package resin is located on the second supporting element, the package resin packages the dielectric layer, the first metal layer, the second metal layer, the first supporting element, and the electronic component into one piece and fastens it onto the second supporting element, and one end of the first supporting element is exposed to the outside of the first supporting element.

12. The semiconductor package having an insulating substrate as claimed in claim 10, wherein the first metal layer and the second metal layer are made of copper or copper alloy.

13. The semiconductor package having an insulating substrate as claimed in claim 10, wherein the first metal layer and the second metal layer are made of aluminum or aluminum alloy.

14. The semiconductor package having an insulating substrate as claimed in claim 10, wherein there is a soldering material connecting layer located between the first metal layer and the first supporting element, and another soldering material connecting layer is located between the second metal layer and the second supporting element.

15. The semiconductor package having an insulating substrate as claimed in claim 9, wherein there is a connecting element located between the first supporting element and the electronic component, and the connecting element is electrically connected with the first supporting element and the electronic component.

16. The semiconductor package having an insulating substrate as claimed in claim 9, wherein the first supporting element is a metal guiding frame, and the second supporting element is a heat-conducting base.

17. The semiconductor package having an insulating substrate as claimed in claim 9, wherein the electronic component is an IC chip.
